(19) United States
(12) Patent Application Publication
(10) Pub. No.: US 2025/0224454 A1
(43) Pub. Date: Jul. 10, 2025

(54) INSPECTION DEVICE, INSPECTION METHOD, AND METHOD FOR MANUFACTURING BATTERY

(71) Applicant: KABUSHIKI KAISHA TOSHIBA, Tokyo (JP)

(72) Inventors: Yoshihiro HIGASHI, Komatsu Ishikawa (JP); Akira KIKITSU, Yokohama Kanagawa (JP); Satoshi SHIROTORI, Yokohama Kanagawa (JP)

(73) Assignee: KABUSHIKI KAISHA TOSHIBA, Tokyo (JP)

(21) Appl. No.: 18/999,231

(22) Filed: Dec. 23, 2024

(30) Foreign Application Priority Data
Jan. 4, 2024 (JP) 2024-000318

(51) Int. Cl. G01R 31/385; G01R 31/367; G01R 33/10

(52) U.S. Cl. CPC G01R 31/386; G01R 31/367; G01R 33/10

(57) ABSTRACT

According to one embodiment, an inspection device includes an acquisitor configured to acquire data obtained from an inspection target, and a processor configured to perform a first operation of processing the data acquired by the acquisitor. The data includes magnetic field data being two-dimensional regarding a plane including a first direction and a second direction crossing the first direction. The plane includes a first region, a second region, a first position, a second position, and a third position. The magnetic field data includes a first region data regarding the first region and a second region data regarding the second region. In the first operation, the processor is configured to inspect the inspection target based on difference data between the first region data and a second region inversion data obtained by inverting a magnetic field value included in the second region data in the first direction.

### CROSS-REFERENCE TO RELATED APPLICATIONS

This application is based upon and claims the benefit of priority from Japanese Patent Application No. 2024-000318, filed on Jan. 4, 2024; the entire contents of which are incorporated herein by reference.

### FIELD

Embodiments described herein relate generally to an inspection device, an inspection method, and a method for manufacturing a battery.

### BACKGROUND

For example, an inspection target, such as a battery, is inspected by detecting a magnetic field generated from the inspection target. Higher accurate inspection is desired.

### BRIEF DESCRIPTION OF THE DRAWINGS

FIG. 1 is a schematic diagram illustrating an inspection device according to a first embodiment;

FIG. 2 is a flowchart illustrating an operation of the inspection device according to the first embodiment;

FIG. 3 is a schematic diagram illustrating the inspection device according to the first embodiment;

FIG. 4 is a schematic diagram illustrating the inspection device according to the first embodiment;

FIG. 5 is a schematic diagram illustrating the inspection device according to the first embodiment;

FIG. 6 is a schematic diagram illustrating the inspection device according to the first embodiment;

FIG. 7 is a schematic diagram illustrating the inspection device according to the first embodiment;

FIG. 8 is a schematic diagram illustrating the inspection device according to the first embodiment;

FIG. 9 is a schematic diagram illustrating the inspection device according to the first embodiment; and

FIG. 10 is a flowchart illustrating a method for manufacturing a battery according to a third embodiment.

### DETAILED DESCRIPTION

According to one embodiment, an inspection device includes an acquisitor configured to acquire data obtained from an inspection target, and a processor configured to perform a first operation of processing the data acquired by the acquisitor. The data includes magnetic field data being two-dimensional regarding a plane including a first direction and a second direction crossing the first direction. The plane includes a first region, a second region, a first position, a second position, and a third position. A direction from the first region to the second region is along the first direction. The third position is a midpoint between the first position and the second position in the first direction. The first region is between the first position and the third position in the first direction. The second region is between the third position and the second position in the first direction. The magnetic field data includes a first region data regarding the first region and a second region data regarding the second region. In the first operation, the processor is configured to inspect the inspection target based on difference data between the first region data and a second region inversion data obtained by inverting a magnetic field value included in the second region data in the first direction.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

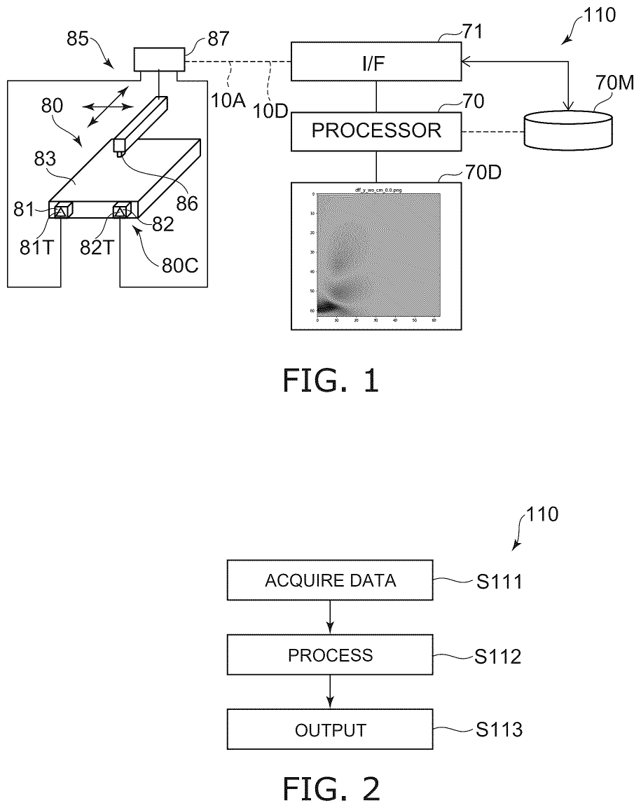

FIG. 1 is a schematic diagram illustrating an inspection device according to a first embodiment.

FIG. 2 is a flowchart illustrating an operation of the inspection device according to the first embodiment.

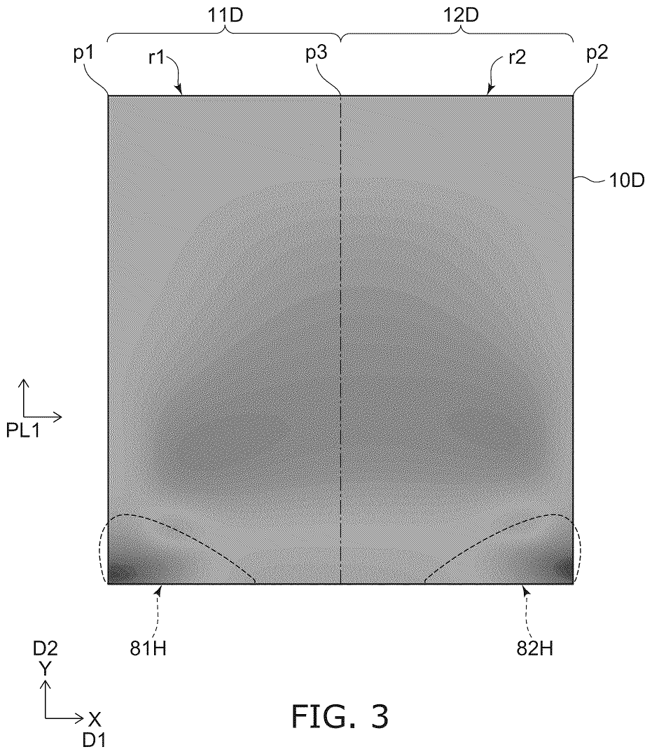

FIGS. 3 to 7 are schematic diagrams illustrating the inspection device according to the first embodiment.

As shown in FIG. 1, an inspection device 110 according to the embodiment includes an acquisitor 71 and a processor 70 The acquisitor 71 is configured to acquire data 10A obtained from an inspection target 80. The processor 70 is configured to perform a first operation of processing the data 10A acquired by the acquisitor 71. The acquisitor 71 is, for example, an interface. The processor 70 may be, for example, a processing circuitry (e.g., an electric circuit).

FIG. 2 illustrates an inspection method performed by the inspection device 110. As shown in FIG. 2, for example, the acquisitor 71 acquires data 10A (step S111). For example, the processor 70 processes the data 10A (step S112). For example, the processor 70 outputs a processing result (step S113). The processing results include inspection results.

In one example, the inspection target 80 may be a battery 80C. The battery 80C may include, for example, a first electrode 81, a second electrode 82, and a battery section 83. The battery section 83 is provided, for example, between the first electrode 81 and the second electrode 82.

In one example, in inspecting the battery 80C, a voltage is applied between the first electrode 81 and the second electrode 82. By applying the voltage, a current flows between the first electrode 81 and the second electrode 82. Electric current generates a magnetic field. The generated magnetic field is detected by a magnetic field sensor 85. The magnetic field sensor 85 may include a sensor element 86 and a controller 87 (for example, control circuitry). The relative position between sensor element 86 and inspection target 80 is changed.

Thus, the magnetic field sensor 85 is configured to acquire magnetic field data 10D being two-dimensional from the inspection target 80. The controller 87 can control, for example, a change in the relative position between the sensor element 86 and the inspection target 80. The controller 87 can control the orientation of the sensor element 86, for example. The sensor element 86 can detect the magnetic field in any direction. The controller 87 may be capable of processing signals obtained from the sensor element 86, for example. The processing the signal may include, for example, amplification. The processing the signal may include any processing including, for example, A/D conversion. Magnetic field data 10D being two-dimensional is supplied from the controller 87 to the acquisitor 71, for example.

Any wired or wireless method may be used for communication (data exchange) between the magnetic field sensor 85 and the acquisitor 71. The magnetic field data 10D being two-dimensional may be stored in a storage 70M, for example.

The magnetic field data 10D obtained from the inspection target 80 includes the magnetic field data 10D being two-dimensional being two-dimensional. FIG. 3 schematically illustrates magnetic field data 10D. The magnetic field data 10D being two-dimensional relates to a plane PL1 including a first direction D1 and a second direction D2 crossing the first direction D1. In FIG. 3, the magnetic field strength in the first direction D1 and the second direction D2 is shown by the shading of the image.

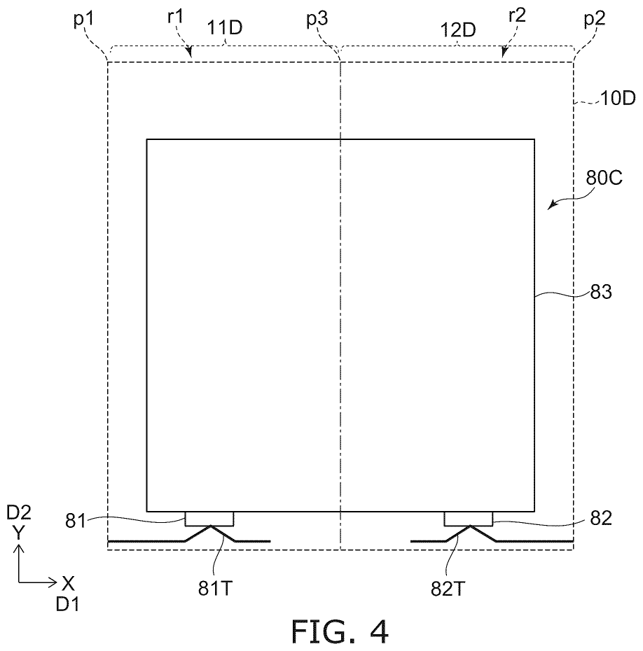

FIG. 4 shows the positional relationship between the magnetic field data 10D being two-dimensional and the battery 80C in this example. As shown in FIG. 4, the magnetic field data 10D may include information regarding the magnetic field in a wider area than the battery 80C.

As shown in FIGS. 3 and 4, the magnetic field data 10D obtained from the inspection target 80 may include a magnetic field caused by a terminal that supplies a voltage (signal) to the first electrode 81 and the second electrode 82. In this example, the magnetic field data 10D being two-dimensional includes a first terminal magnetic field 81H caused by a first terminal 81T electrically connected to the first electrode 81 and a second terminal magnetic field 82H caused by a second terminal 82T electrically connected to the second electrode 82.

As shown in FIG. 3, the plane PL1 includes a first region r1, a second region r2, a first position p1, a second position p2, and a third position p3. A direction from the first region r1 to the second region r2 is along the first direction D1. These positions are positions in the first direction D1. The third position p3 is a midpoint between the first position p1 and the second position p2 in the first direction D1. The first region r1 is between the first position p1 and the third position p3 in the first direction D1. The second region r2 is between the third position p3 and the second position p2 in the first direction D1. The magnetic field data 10D includes first region data 11D regarding the first region r1 and second region data 12D regarding the second region r2.

The first region data 11D corresponds to magnetic field data (magnetic field value) in the first region 11 between the first position p1 and the third position p3. The second region data 12D corresponds to magnetic field data (magnetic field value) in the second region 12 between the third position p3 and the second position p2.

In the first operation, the processor 70 inspects the inspection target 80 based on difference data between the first region data 11D and the second region inverted data 12R obtained by inverting the magnetic field value included in the second region data 12D in the first direction D1. For example, if the difference data exceeds a threshold value, it is determined that there is a defect.

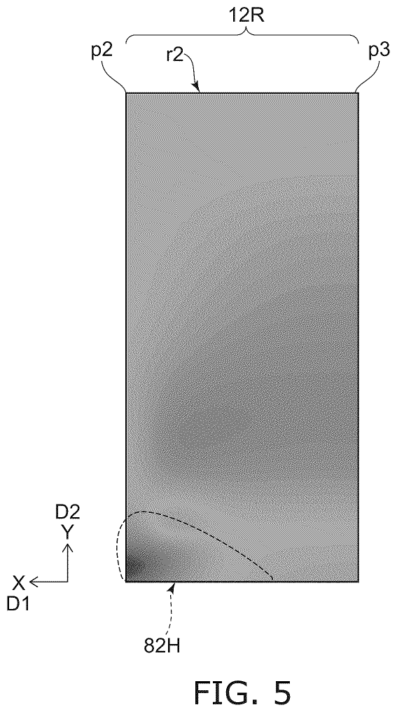

FIG. 5 illustrates the second region inverted data 12R. The second region inverted data 12R is obtained by inverting the second region data 12D illustrated in FIG. 3 with respect to the first direction D1. The difference data between the second region inverted data 12R (FIG. 5) and the first region data 11D (see FIG. 3) is calculated.

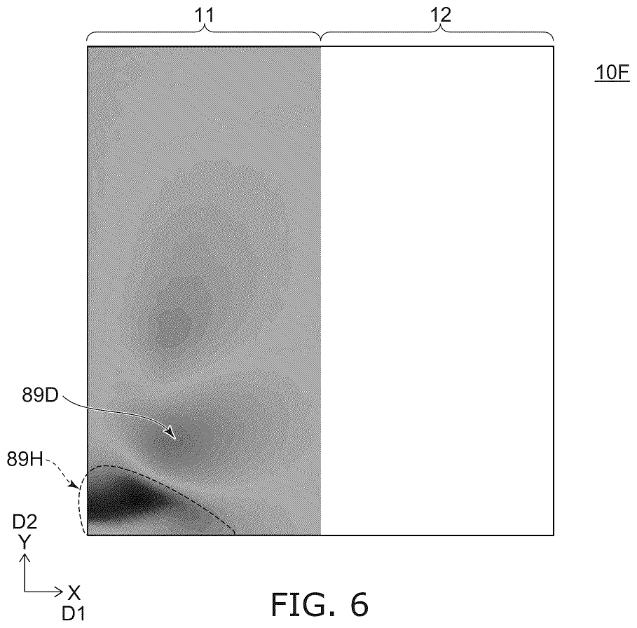

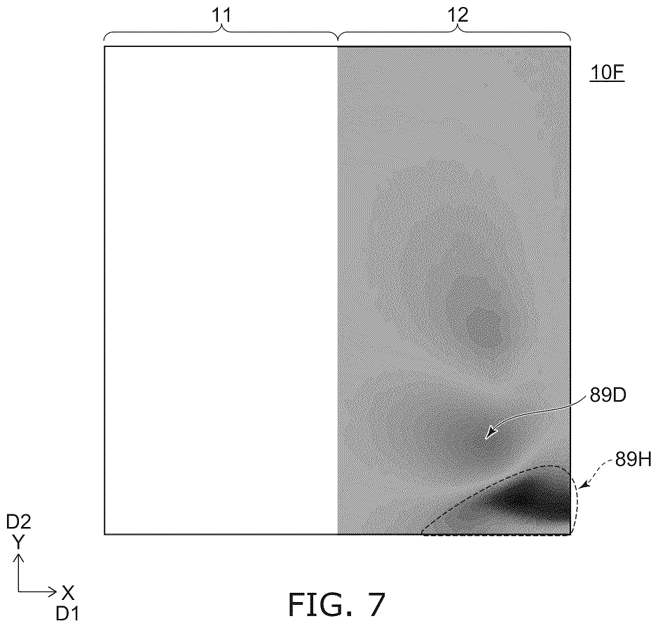

FIGS. 6 and 7 illustrate the difference data 10F. In these figures, the magnitude of the value of the difference data 10F is shown by the shading of the image. As described above, the difference data 10F corresponds to the difference between the second region inverted data 12R and the first region data 11D. Therefore, the number of data included in the distribution of difference data 10F is ½ of the number of magnetic field data 10D being two-dimensional before processing. As shown in FIGS. 6 and 7, the difference data 10F may include a terminal-induced magnetic field 89H corresponding to the difference between the first terminal magnetic field 81H and the second terminal magnetic field 82H. Since the terminal-induced magnetic field 89H is not caused by the inspection target 80, it may be excluded from the process for inspection of the inspection target 80. For example, the terminal-induced magnetic field 89H may be removed from the difference data 10F. In the following, attention will be paid to data excluding the terminal-induced magnetic field 89H. In FIGS. 6 and 7, the value of the difference data 10F is locally large in a region excluding the terminal-induced magnetic field 89H. This position corresponds to the position of a defect 89D in the inspection target 80.

In the example of FIG. 6, a case is illustrated in which a defect 89D exists in the first region 11. In the example of FIG. 7, a case is illustrated in which a defect 89D exists in the second region 12.

In the embodiment, an approximate position of the defect 89D may be estimated from information other than the difference data 10F described above. For example, the processor 70 may estimate the position of the defect 89D from the magnetic field data 10D being two-dimensional before the first operation described above. However, the accuracy of the position of the defect 89D estimated from the magnetic field data 10D being two-dimensional is low. On the other hand, by using the difference data 10F regarding the difference between the two region data, the position of the defect 89D can be derived with high accuracy.

In the embodiment, it cannot be accurately determined whether the position of the defect 89D derived using the difference data 10F exists in the first region 11 or the second region 12. Therefore, the position of the defect 89D can be accurately determined by using the difference data 10F and the estimation result of the rough position of the defect 89D.

As described above, the processor 70 may be configured to determine the position of the defect 89D based on the estimation result that the position of the defect 89D of the inspection target 80 exists in either the first region 11 or the second region 12 and the difference data 10F. The first region 11 corresponds to a region from which the first region data 11D is obtained. The second region 12 corresponds to a region from which the second region data 12D is obtained. The order of the estimation and the first operation is arbitrary.

The estimation that the position of the defect 89D of the inspection target 80 exists in either the first region 11 or the second region 12 may be performed based on at least one of the following a first processing, a second processing, and a third processing.

In the first process, the maximum value of the magnetic field in the first region 11 is set as a first maximum value based on the magnetic field data 10D being two-dimensional. The maximum value of the magnetic field in the second region 12 is defined as a second maximum value. If the first maximum value is higher than the second maximum value, it is estimated that the position of the defect 89D is included in the first region 11. If the first maximum value is not higher than the second maximum value, it is estimated that the position of the defect 89D is included in the second region 12.

In the second process, the estimation is performed with reference to the positions of the first electrode 81 and the second electrode 82 included in the battery 80C. That is, based on the magnetic field data 10D being two-dimensional, the distance between the position (first position) at which the maximum value (first maximum value) of the magnetic field in the first region 11 is obtained and the position of the first electrode 81 is set as the first distance. The distance between the position (second position) at which the maximum value (second maximum value) of the magnetic field in the second region 12 is obtained and the position of the second electrode 82 is set as a second distance based on the magnetic field data 10D being two-dimensional. If the first distance is shorter than the second distance, it is estimated that the position of the defect 89D is included in the first region 11. If the first distance is not shorter than the second distance, it is estimated that the position of the defect 89D is included in the second region 12.

In the third process, it is estimated that the position of the defect 89D of the inspection target 80 is present in either the first region 11 or the second region 12 based on the past inspection result regarding the inspection target 80. The past inspection result may be stored in the storage 70M, for example. In the third process, information stored in the storage 70M is read, and estimation is performed based on the read information. The past inspection result regarding the inspection target 80 may be obtained by, for example, machine learning.

In the first process and the second process described above, the maximum value of the magnetic field may be calculated by excluding the influence of the magnetic field (terminal-caused magnetic field 89H) caused by the terminal that supplies the voltage (signal) applied to the first electrode 81 and the second electrode 82. In one example, the magnetic field caused by the terminal (terminal-caused magnetic field 89H) may be removed or reduced based on the difference between the magnetic field data 10D being two-dimensional of the known normal product, and the magnetic field data 10D being two-dimensional of the inspection target 80.

As described above, the processor 70 may be configured to derive the estimation result that the position of the defect 89D of the inspection target 80 exists in either the first region 11 or the second region 12 from the magnetic field data 10D being two-dimensional.

In the embodiment, the estimation result indicating that the position of the defect 89D of the inspection target 80 exists in either the first region 11 or the second region 12 may be derived based on the past inspection results or the like.

In the examples of FIGS. 6 and 7, the position of the defect 89D is illustrated in the image data. The position of the defect 89D may be output as coordinate values. By displaying the position of the defect 89D in the image data, the user of the inspection device 110 can easily recognize the inspection results.

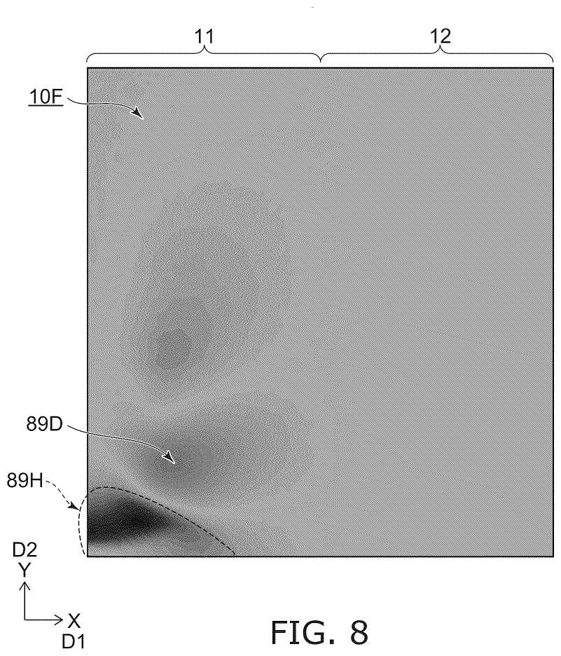

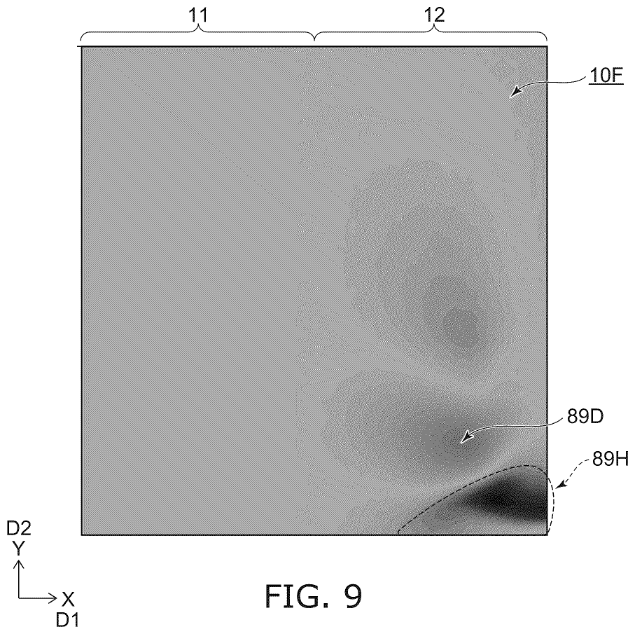

FIGS. 8 and 9 are schematic diagrams illustrating the inspection device according to the first embodiment.

FIG. 8 corresponds to the inspection results in FIG. 6. The difference data 10F is displayed in the first region 11 illustrated in FIG. 8. In FIG. 8, an image corresponding to the case where the difference is smaller than the threshold value is displayed in the second region 12. Thereby, the user of the inspection device 110 can easily recognize the position of the defect 89D. FIG. 9 corresponds to the inspection results of FIG. 7. The difference data 10F is displayed in the second region 12 illustrated in FIG. 9. In FIG. 9, an image corresponding to the case where the difference is smaller than the threshold value is displayed in the first region 11. Thereby, the user of the inspection device 110 can easily recognize the position of the defect 89D.

Such an image (inspection result) may be displayed on, for example, the display device 70D (see FIG. 1). The inspection device 110 may include at least one of display device 70D or storage 70M.

In the embodiment, the magnetic field data 10D being two-dimensional may relate to the component in the second direction D2. For example, the second direction D2 may be perpendicular to the first direction D1. For example, in inspecting the battery 80C, there is a difference in characteristics between the first electrode 81 and the second electrode 82 based on positive and negative polarities. Therefore, the value of the magnetic field included in the magnetic field data 10D being two-dimensional is asymmetric with respect to the first direction D1. In the embodiment, the position of the defect 89D can be accurately derived by deriving the difference between the magnetic field data 10D being second-dimensional of the component in the second direction D2.

In the embodiment, the magnetic field data 10D being two-dimensional may include a magnetic field component in the second direction D2. The magnetic field component along the first direction D1 may be used for part of the inspection. For example, the magnetic field component along the first direction D1 may be used to roughly estimate the position of the defect 89D in the inspection target 80.

As shown in FIG. 4, the direction from the first electrode 81 to the second electrode 82 may be along the first direction D1 mentioned above of the magnetic field data 10D being two-dimensional. The direction from the first terminal 81T that supplies voltage (signal) to the first electrode 81 to the second terminal 82T that supplies voltage (signal) to the second electrode 82 may be along the first direction D1. The magnetic field data 10D being two-dimensional includes the distribution of the magnetic field generated from the battery 80C when a voltage (signal) is applied between the first electrode 81 and the second electrode 82. The voltage (signal) may be supplied from the controller 87 (FIG. 1). The voltage (signal) may be, for example, an alternating voltage (alternating signal). The magnetic field data 10D being two-dimensional may include data obtained by a detection based on the frequency of AC voltage. For example, the controller 87 may include a lock-in amplifier. The lock-in amplifier may detect magnetic field strength extracted in synchronization with the alternating voltage (alternating signal). The extracted magnetic field strength may be used as magnetic field data 10D. Inspection with higher accuracy becomes possible.

### Second Embodiment

The second embodiment relates to an inspection method. In the inspection method, the data 10A obtained from the inspection target 80 is acquired (step S111 in FIG. 2). The data 10A is processed (step S112 in FIG. 2).

The data 10A includes the magnetic field data 10D being two-dimensional regarding the plane PL1 including the first direction D1 and the second direction D2 crossing the first direction D1. The plane PL1 includes the first position p1, the second position p2, and the third position p3. The third position p3 is the midpoint between the first position p1 and the second position p2 in the first direction D1. The magnetic field data 10D includes the first region data 11D between the first position p1 and third position p3, and the second region data 12D between the third position p3 and second position p2.

In the embodiment, the inspection target 80 is inspected based on the difference data 10F between the first region data 11D and the second region inverted data 12R in which the magnetic field value included in the second region data 12D is inverted in the first direction D1. Highly accurate inspections can be performed. The inspection results may be output (step S113 in FIG. 2).

For example, the magnetic field data 10D relates to a component in the second direction D2. The second direction D2 may be perpendicular to the first direction D1. The inspection target 80 may be the battery 80C. The battery 80C includes the first electrode 81, the second electrode 82, and the battery section 83 between the first electrode 81 and the second electrode 82. The direction from the first electrode 81 to the second electrode 82 is along the first direction D1 of the magnetic field data 10D being two-dimensional. For example, the magnetic field data 10D being two-dimensional includes the distribution of the magnetic field generated from the battery 80C when an AC voltage (AC signal) is applied between the first electrode 81 and the second electrode 82.

In the embodiment, the position of the defect 89D of the inspection target 80 may be determined based on the estimation result that the position of the defect 89D exists in either the first region 11 or the second region 12 and the difference data 10F described above. The first region 11 corresponds to a region where the first region data 11D is obtained. The second region 12 corresponds to a region where the second region data 12D is obtained.

### Third Embodiment

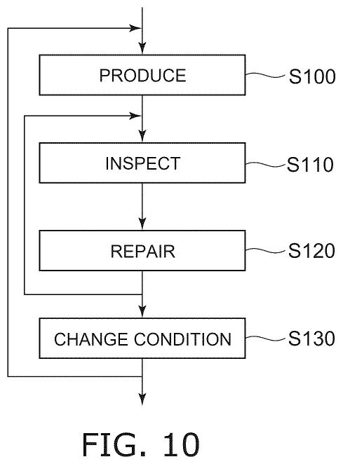

FIG. 10 is a flowchart illustrating a method for manufacturing a battery according to a third embodiment.

As shown in FIG. 10, a battery 80C to be the inspection target 80 is produced (step S100). The battery 80C is inspected using the inspection method according to the second embodiment (step S110). In the inspection, the processing described in connection with the first embodiment and the second embodiment may be performed. Highly accurate inspections can be performed.

For example, the battery 80C may include the first electrode 81, the second electrode 82, and the battery section 83 between the first electrode 81 and the second electrode 82. The direction from the first electrode 81 to the second electrode 82 is along the first direction D1 of the magnetic field data 10D being two-dimensional. For example, the magnetic field data 10D being two-dimensional includes the distribution of the magnetic field generated from the battery 80C when an AC voltage is applied between the first electrode 81 and the second electrode 82.

For example, the position of the defect 89D of the inspection target 80 may be determined based on the estimation result that the position of the defect 89D exists in either the first region 11 or the second region 12 and the difference data 10F. The first region 11 corresponds to first region data 11D. The second region 12 corresponds to second region data 12D.

As shown in FIG. 10, repairs may be performed based on the inspection results (step S120). The inspection target 80 (battery 80C) after repair may be inspected again.

As shown in FIG. 10, the conditions may be changed based on the inspection results (step S130). For example, the conditions include conditions for forming the battery 80C. For example, changing the conditions includes changing the material of the battery 80C. For example, the change in conditions may include a change in the design of the battery 80C. The inspection device 110 and inspection method according to the embodiment may be used for failure analysis of the inspection target 80.

The embodiments may include the following Technical proposals (e.g., configurations):

### Technical Proposal 1

An inspection device, comprising:
an acquisitor configured to acquire data obtained from an inspection target; and
a processor configured to perform a first operation of processing the data acquired by the acquisitor,
the data including magnetic field data being two-dimensional regarding a plane including a first direction and a second direction crossing the first direction,
the plane including a first region, a second region, a first position, a second position, and a third position,
a direction from the first region to the second region being along the first direction,
the third position being a midpoint between the first position and the second position in the first direction,
the first region being between the first position and the third position in the first direction,
the second region being between the third position and the second position in the first direction,
the magnetic field data including a first region data regarding the first region and a second region data regarding the second region, and
in the first operation, the processor being configured to inspect the inspection target based on difference data between the first region data and a second region inversion data obtained by inverting a magnetic field value included in the second region data in the first direction.

### Technical Proposal 2

The inspection device according to Technical proposal 1, wherein
the magnetic field data relates to a component in the second direction.

### Technical Proposal 3

The inspection device according to Technical proposal 1 or 2, wherein
the second direction is perpendicular to the first direction.

### Technical Proposal 4

The inspection device according to any one of Technical proposals 1-3, wherein
the inspection target is a battery.

### Technical Proposal 5

The inspection device according to Technical proposal 4, wherein
the battery includes a first electrode, a second electrode, and a battery section between the first electrode and the second electrode, and
a direction from the first electrode to the second electrode is along the first direction of the magnetic field data being two-dimensional.

### Technical Proposal 6

The inspection device according to Technical proposal 5, wherein
the magnetic field data being two-dimensional includes a distribution of a magnetic field generated from the battery when an AC voltage is applied between the first electrode and the second electrode.

### Technical Proposal 7

The inspection device according to any one of Technical proposals 1-6, wherein
the processor is configured to determine a position of a defect based on the difference data and an estimation result that the position of the defect of the inspection target exists in either the first region or the second region,
the first region corresponds to the first region data, and the second region corresponds to the second region data.

### Technical Proposal 8

The inspection device according to Technical proposal 7, wherein
the processor is configured to derive the estimation result from the magnetic field data being two-dimensional.

### Technical Proposal 9

The inspection device according to any one of Technical proposals 1-8, further comprising:
a magnetic field sensor configured to acquire the magnetic field data being two-dimensional from the inspection target.

### Technical Proposal 10

An inspection method, comprising;
acquiring data obtained from an inspection target; and
processing the data for inspecting the inspection target,
the data including magnetic field data being two-dimensional regarding a plane including a first direction and a second direction crossing the first direction,
the plane including a first region, a second region, a first position, a second position, and a third position,
a direction from the first region to the second region being along the first direction,
the third position being a midpoint between the first position and the second position in the first direction,
the first region being between the first position and the third position in the first direction,
the second region being between the third position and the second position in the first direction,
the magnetic field data including a first region data regarding the first region and a second region data regarding the second region,
in the inspection, the inspection target being inspected based on difference data between the first region data and a second region inversion data obtained by inverting a magnetic field value included in the second region data in the first direction.

### Technical Proposal 11

The inspection method according to Technical proposal 10, wherein
the magnetic field data relates to a component in the second direction.

### Technical Proposal 12

The inspection method according to Technical proposal 10 or 11, wherein
the second direction is perpendicular to the first direction.

### Technical Proposal 13

The inspection method according to any one of Technical proposals 10-12, wherein
the inspection target is a battery.

### Technical Proposal 14

The inspection method according to Technical proposal 13, wherein
the battery includes a first electrode, a second electrode, and a battery section between the first electrode and the second electrode, and
a direction from the first electrode to the second electrode is along the first direction of the magnetic field data being two-dimensional.

### Technical Proposal 15

The inspection method according to Technical proposal 14, wherein
the magnetic field data being two-dimensional includes a distribution of a magnetic field generated from the battery when an AC voltage is applied between the first electrode and the second electrode.

### Technical Proposal 16

The inspection method according to any one of Technical proposals 10-15, further comprising:
determining a position of a defect based on the difference data and an estimation result that the position of the defect of the inspection target exists in either the first region or the second region.

### Technical Proposal 17

A method for manufacturing a battery, comprising:
producing a battery to be the inspection target; and
inspecting the battery by the inspection method according to any one of Technical proposals 10-12.

### Technical Proposal 18

The method for manufacturing the battery according to Technical proposal 17, wherein
the battery includes a first electrode, a second electrode, and a battery section between the first electrode and the second electrode, and
a direction from the first electrode to the second electrode is along the first direction of the magnetic field data being two-dimensional.

### Technical Proposal 19

The method for manufacturing the battery according to Technical proposal 18, wherein
the magnetic field data being two-dimensional includes a distribution of a magnetic field generated from the battery when an AC voltage is applied between the first electrode and the second electrode.

### Technical Proposal 20

The method for manufacturing the battery according to any one of Technical proposals 17-19, further comprising:
determining a position of a defect based on the difference data and an estimation result that the position of the defect of the inspection target exists in either the first region or the second region,
the first region corresponding to the first region data, and
the second region corresponding to the second region data. According to the embodiment, it is possible to provide an inspection device, an inspection method, and a method for manufacturing a battery that are capable of highly accurate inspection.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in inspection devices such as acquisitors, processors, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all inspection devices, all inspection methods, and all methods for manufacturing batteries practicable by an appropriate design modification by one skilled in the art based on the inspection devices, the inspection methods, and the methods for manufacturing batteries described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. An inspection device, comprising:
an acquisitor configured to acquire data obtained from an inspection target; and
a processor configured to perform a first operation of processing the data acquired by the acquisitor, the data including magnetic field data being two-dimensional regarding a plane including a first direction and a second direction crossing the first direction, the plane including a first region, a second region, a first position, a second position, and a third position, a direction from the first region to the second region being along the first direction, the third position being a midpoint between the first position and the second position in the first direction, the first region being between the first position and the third position in the first direction, the second region being between the third position and the second position in the first direction, the magnetic field data including a first region data regarding the first region and a second region data regarding the second region, and in the first operation, the processor being configured to inspect the inspection target based on difference data between the first region data and a second region inversion data obtained by inverting a magnetic field value included in the second region data in the first direction.

2. The device according to claim 1, wherein the magnetic field data relates to a component in the second direction.

3. The device according to claim 1, wherein the second direction is perpendicular to the first direction.

4. The device according to claim 1, wherein the inspection target is a battery.

5. The device according to claim 4, wherein the battery includes a first electrode, a second electrode, and a battery section between the first electrode and the second electrode, and a direction from the first electrode to the second electrode is along the first direction of the magnetic field data being two-dimensional.

6. The device according to claim 5, wherein the magnetic field data being two-dimensional includes a distribution of a magnetic field generated from the battery when an AC voltage is applied between the first electrode and the second electrode.

7. The device according to claim 1, wherein the processor is configured to determine a position of a defect based on the difference data and an estimation result that the position of the defect of the inspection target exists in either the first region or the second region, the first region corresponds to the first region data, and the second region corresponds to the second region data.

8. The device according to claim 7, wherein the processor is configured to derive the estimation result from the magnetic field data being two-dimensional.

9. The device according to claim 1, further comprising:
a magnetic field sensor configured to acquire the magnetic field data being two-dimensional from the inspection target.

10. An inspection method, comprising;
acquiring data obtained from an inspection target; and
processing the data for inspecting the inspection target, the data including magnetic field data being two-dimensional regarding a plane including a first direction and a second direction crossing the first direction, the plane including a first region, a second region, a first position, a second position, and a third position, a direction from the first region to the second region being along the first direction, the third position being a midpoint between the first position and the second position in the first direction, the first region being between the first position and the third position in the first direction, the second region being between the third position and the second position in the first direction, the magnetic field data including a first region data regarding the first region and a second region data regarding the second region, in the inspection, the inspection target being inspected based on difference data between the first region data and a second region inversion data obtained by inverting a magnetic field value included in the second region data in the first direction.

11. The method according to claim 10, wherein the magnetic field data relates to a component in the second direction.

12. The method according to claim 10, wherein the second direction is perpendicular to the first direction.

13. The method according to claim 10, wherein the inspection target is a battery.

14. The method according to claim 13, wherein the battery includes a first electrode, a second electrode, and a battery section between the first electrode and the second electrode, and a direction from the first electrode to the second electrode is along the first direction of the magnetic field data being two-dimensional.

15. The method according to claim 14, wherein the magnetic field data being two-dimensional includes a distribution of a magnetic field generated from the battery when an AC voltage is applied between the first electrode and the second electrode.

16. The method according to claim 10, further comprising:
determining a position of a defect based on the difference data and an estimation result that the position of the defect of the inspection target exists in either the first region or the second region.

17. A method for manufacturing a battery, comprising:
producing a battery to be the inspection target; and
inspecting the battery by the inspection method according to claim 10.

18. The method for manufacturing the battery according to claim 17, wherein the battery includes a first electrode, a second electrode, and a battery section between the first electrode and the second electrode, and a direction from the first electrode to the second electrode is along the first direction of the magnetic field data being two-dimensional.

19. The method for manufacturing the battery according to claim 18, wherein the magnetic field data being two-dimensional includes a distribution of a magnetic field generated from the battery when an AC voltage is applied between the first electrode and the second electrode.

20. The method for manufacturing the battery according to claim 17, further comprising:
determining a position of a defect based on the difference data and an estimation result that the position of the defect of the inspection target exists in either the first region or the second region, the first region corresponding to the first region data, and the second region corresponding to the second region data.
